(19) United States
(12) Patent Application Publication
(10) Pub. No.: US 2008/0286537 A1
(43) Pub. Date: Nov. 20, 2008

(54) PRE-DRY TREATMENT OF INK IN DECORATIVE PLASTIC GLAZING

(76) Inventors: Christophe Lefaux, Ann Arbor, MI (US); Sunitha K. Grandhee, Novi, MI (US)

Correspondence Address: EXATEC;C/O BRINKS HOFER GILSON & LIONE, 524 South Main Street, Suite 200, Ann Arbor, MI, 48104, US

(21) Appl. No.: 12/117,960

(22) Filed: May 9, 2008

Related U.S. Application Data
(60) Provisional application No. 60/916,859, filed on May 9, 2007.

(51) Int. Cl. B32B 3/10; B05D 5/06; B05D 3/06; C23C 16/513; C23C 26/00; C23C 16/44; C23C 14/48; C23C 14/34; C23C 14/35

(52) U.S. Cl. 428/203; 427/164; 427/511; 427/569; 427/491; 427/582; 427/525; 427/580; 204/192.1; 204/192.16

(57) ABSTRACT

An economical method of manufacturing a plastic glazing assembly having a decorative marking and/or opaque border printed from a thermally curable ink is presented. This method includes the steps of forming a substantially transparent plastic panel; printing an opaque pattern from an ink, the printed pattern being in contact with the plastic panel; pre-drying the ink of the printed pattern to a tack-free condition; applying a weather resistant layer on the printed pattern and on the plastic panel; curing the ink of the printed pattern and the weather resistant layer; and depositing an abrasion resistant layer on the weather resistant layer. In this process the drying of the ink substantially removes the solvent from the ink without substantially curing the ink.

This application claims the benefit of U.S. Provisional Application Ser. No. 60/916,859 filed on May 9, 2007, entitled “JET DRY TREATMENT OF DECORATIVE PLASTIC GLAZING,” the entire contents of which are incorporated herein by reference.

### FIELD

This invention relates to plastic glazing panels having a decorative marking or opaque border printed from an ink and dried prior to the application of a weather resistant coating.

### BACKGROUND

Plastic materials are being used in a number of automotive engineering applications to enhance vehicle styling. For example, plastic materials are currently used in the manufacturing of such parts and components as B-pillars, headlamps, and sunroofs. An emerging application for transparent plastic materials is automotive window systems. When a transparent plastic material is used to manufacture an automotive window, regulatory requirements call for the window to include some form of identification marking or logo. In addition, manufacturer's find it desirable for the automotive window to include an opaque fade-out border in order to enhance the overall appearance of the installed window. Finally, in order for plastic windows to be durable over a period of years, the window is covered by a coating that will provide the window with protection against weathering and scratches/abrasion.

In order to effectively apply an opaque pattern to a plastic window in the form of an identification marking and a fade-out border, inks that are used must not only adhere to the surface of the plastic window, but also must be compatible with the protective coating system that is applied to the window's surface. Any ink used to mark the surface of a plastic window must not be softened, damaged, or removed during the application of the protective coating system. In addition, the inks need to be able to survive the rigorous testing required to qualify the product by the automotive industry.

The use of a thermally curable ink to apply an opaque pattern to a plastic panel requires the ink to be substantially cured prior to the application of a protective coating. If the ink is not substantially cured, premature failure of the decorated glazing panels may be encountered. A thermally curable ink can take anywhere from 30 to 60 minutes to cure when exposed to a temperature greater than about 100° C. Thus, a thermally curable ink requires a long process time and the significant consumption of energy in order to be used on a plastic glazing panel. The automotive industry is continually looking for methods that can either enhance productivity (e.g., reduce cycle time) or lower manufacturing costs.

Therefore, there is a need in the industry to be able to manufacture a plastic glazing system with a higher level of productivity and lower cost using a thermally curable ink.

### SUMMARY

An economical method of manufacturing a plastic glazing assembly having a decorative marking and/or opaque border printed from a thermally curable ink is presented. This method includes the steps of forming a substantially transparent plastic panel; printing an opaque pattern from an ink, the printed pattern being in contact with the plastic panel; pre-drying the ink of the printed pattern to a tack-free condition; applying a weather resistant layer on the printed pattern and on the plastic panel; curing the ink of the printed pattern and the weather resistant layer; and depositing an abrasion resistant layer on the weather resistant layer. In this process the drying of the ink substantially removes the solvent from the ink without substantially curing the ink.

In one embodiment of the present invention, the pre-drying step utilizes a “jet dry” method where heated air is forced to flow onto or over the surface of the printed ink. In this “jet dry” method, the air is heated to about 70° C. The exposure of the printed ink to the flow of heated air is performed for less than about 5 minutes, with between about 2 to 4 minutes being preferred. The heating of the air during the “jet dry” method may be ramped upward from about 50° C. near the beginning of the drying step to about 70° C. near the end of the drying step.

In another embodiment of the present invention, the pre-drying step involves a flash-off period at ambient temperature of less than about 30 minutes, with about 15 minutes being preferred.

In yet another embodiment of the present invention the curing of the printed ink occurs simultaneously with the curing of the weather resistant layer. The curing mechanism for the printed ink and the weather resistant layer may involve various mechanisms, such as UV absorption, thermal absorption, condensation addition, thermally driven entanglement, cross-linking induced by cationic or anionic species, or a combination thereof.

In another aspect of the present invention, the glazing panel comprises a plastic panel, a printed ink, a weather resistant layer, and an abrasion resistant layer. The plastic panel is made of a substantially transparent resin, such as polycarbonate. The printed ink being comprised of a polyester resin, polycarbonate resin, or acrylic resin, or a mixture or combination thereof. The weather resistant layer may include a single layer or multiple layers, such as a primer and a topcoat. The weather resistant layer uses ultraviolet absorbing (UVA) molecules to protect the plastic panel from UV radiation. The abrasion resistant layer is deposited using a vacuum deposition technique. One example of an abrasion resistant layer includes, but is not limited to, silicon oxy-carbide having a composition ranging from SiOₓ to SiOₓC_{y}H_{z}.

In another aspect of the present invention, the plastic glazing panel made using the process of the present invention is found to be able to pass rigorous testing. Such testing includes adhesion testing according to ASTM D3359-95 for 10 or more days of water immersion at elevated temperature and exposure to high temperature and humidity in a Cataplasma Treatment Test (Method No. 039E, Dow Automotive).

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a depiction of an automobile incorporating a plastic window according to the principles of the present invention.

FIG. 2 is a schematic of a manufacturing process for a plastic glazing assembly according to one embodiment of the present invention.

FIG. 3 is a schematic of the printing, partial drying, and curing steps depicted as a function of time for a thermal curable ink in a conventional manufacturing process for a decorated glazing panel.

FIG. 4A is a schematic of the printing and “jet dry” steps depicted as a function of time for a thermal curable ink in a manufacturing process for a decorated glazing panel according to one embodiment of the present invention.

FIG. 4B is a schematic of the printing and “ambient flash-off” steps depicted as a function of time for a thermal curable ink in a manufacturing process for a decorated glazing panel according to one embodiment of the present invention.

FIG. 5 is a diagrammatic representation of a cross-section of a decorated glazing panel according to one embodiment of the present invention.

### DETAILED DESCRIPTION

The following description is merely exemplary in nature and is in no way intended to limit the present disclosure or its application or uses. It should be understood that throughout the description and drawings, corresponding reference numerals indicate like or corresponding parts and features.

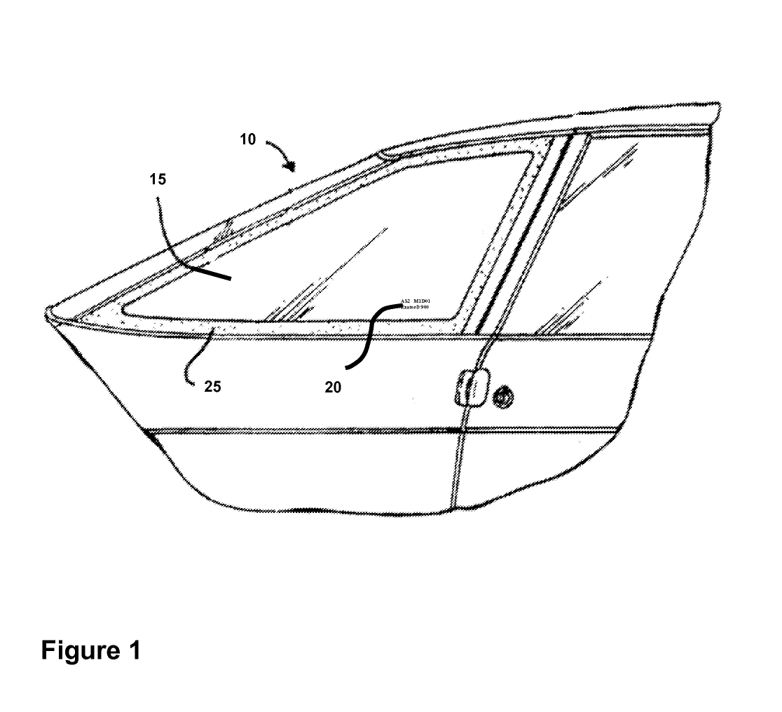

The present invention provides an economical method of manufacturing a plastic glazing panel that exhibits a decorative opaque pattern printed from an ink dried to a tack-free condition, but not cured, prior to being coated with a protective coating system that provides the glazing panel with a high level of weathering and abrasion resistance. Referring to FIG. 1, a plastic glazing panel may be used on an automobile 10 as a movable side window 15. The window 15 is shown with a printed opaque border 25 and printed logo/regulatory information 20. One skilled-in-the-art of automotive design will realize that the plastic glazing panel of the present invention can be used for other automotive windows, such as a backlite, sunroof, and fixed side window, among others. One skilled-in-the-art will also recognize that the plastic glazing panel may be used in many other applications that require optical transparency, including but not limited to, computer displays or monitors, displays for hand-held devices (e.g., cell phones, MP3 players, etc.), lenses, automotive headlamps, motorcycle windshields, helmet visors, and windows used in non-automotive applications, such as for boats, trains, planes, and buildings.

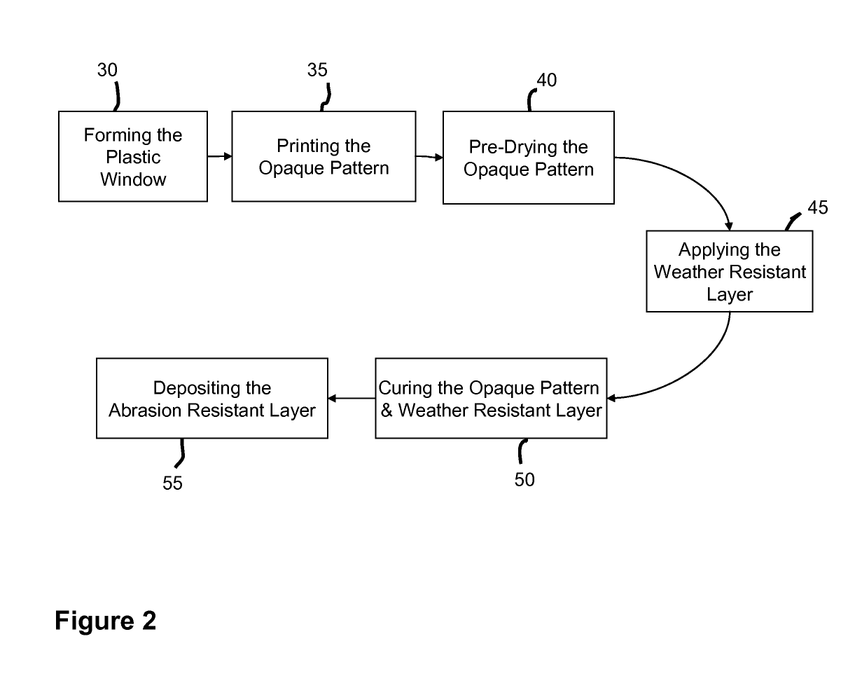

Referring to FIG. 2, an economical manufacturing process according to the principles of the present invention may generally be defined by first forming (step 30) a plastic substrate; then printing (step 35) an opaque pattern; followed by pre-drying (step 40) the printed ink; applying (step 45) a weather resistant layer onto the printed substrate; curing (step 50) the printed ink and the weather resistant layer, and finally depositing (step 55) an abrasion resistant layer.

The substantially transparent plastic panel is formed in step 30, into a window, e.g., vehicle window, from plastic pellets or sheets through the use of any known technique to those skilled in the art, such as extrusion; molding, which includes injection molding, blow molding, and compression molding; or thermoforming, which includes thermal forming, vacuum forming, and cold forming. It is to be noted that the forming of a window using plastic sheet may occur prior to printing (step 35) as shown in FIG. 1, after printing (step 35) and pre-drying (step 40) of the ink, or after application (step 45) and curing (step 50) of the weather resistant coating without falling beyond the scope or spirit of the present invention. The use of plastic pellets to form the plastic panel is done prior to printing the opaque pattern in step 35.

A substantially opaque pattern referred to in step 35 may be defined as an opaque border and/or decorative marking applied to the plastic panel for decorative purposes, to convey information (e.g., corporate, regulatory, etc.), or to hide or mask other vehicle components (e.g., adhesives). The opaque border may be applied to the periphery of the transparent substrate to form a solid masking border, while a decorative marking may be applied to a portion of the viewing region of the window. The opaque border may further include a fade-out pattern to transition the border into the viewing region of the window. The fade-out pattern may incorporate a variety of shapes of variable size including dots, rectangles (lines), squares, and triangles, among others. The decorative marking may further include any combination of letters, symbols, and numbers including, but not limited to, corporate logos, trademarks, and regulatory designations.

In one embodiment of the present invention, the opaque pattern can be printed onto the surface of the plastic panel via screen printing. Other known methods of printing the opaque pattern on the plastic panel may also be utilized when deemed appropriate. A non-inclusive list of other known printing methods include pad printing, membrane image transfer printing, cylindrical printing, digital printing, robotic dispensing, mask/spray, ink-jet printing, and the like. The thickness of the printed ink may range from about 2 micrometers to about 1 mil (25.4 micrometers) with about 6 to 12 micrometers being preferred.

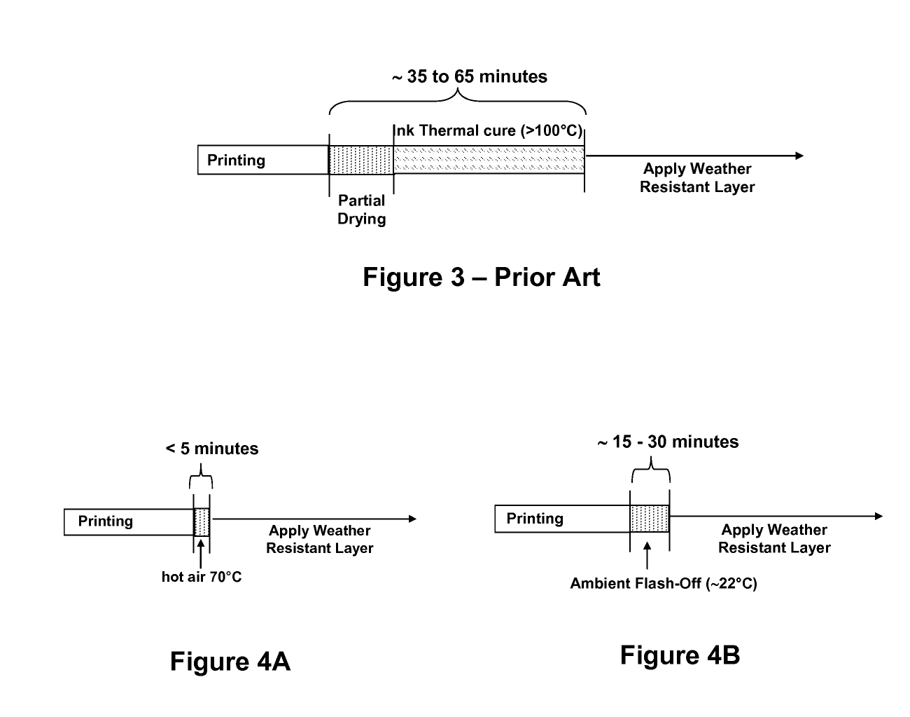

Referring to FIG. 3, in a conventional manufacturing process for a decorative glazing panel, the opaque pattern is printed on to the plastic panel and then the ink is allowed to dry for a period of time, i.e., ˜5 minutes, in order for the ink to set-up or form structure that will allow the panel to be moved without the creation of defects, such as those caused by the ink running or flowing. The ink is then cured at an elevated temperature (greater than about 100° C.) for a substantial period of time, i.e., about 30-60 minutes. Thus, the time required to prepare the decorated panel for application of the weather resistant layer is on the order of about 35 to 65 minutes.

Referring now to FIGS. 4A and 4B, the pre-drying step 40 of the present invention eliminates the need for the step of curing the printed ink prior to the application of the weather resistant layer. The elimination of this curing step reduces manufacturing cost by lowering both process time and energy consumption. The elimination of the curing step further enhances productivity by reducing the overall process time. Although pre-drying the ink may result in partial curing of the ink, the ink is not substantially cured until exposed to a later cure step associated with the curing of the weather resistant layer. As used herein, the term “not substantially cured” means that the ink has structure and is tack-free, but does not exhibit the level of solvent resistance, opacity, or adhesive properties expected to be exhibited by the ink upon being fully cured.

According to the present invention, the pre-drying of the ink in step 40 is done through the use of a “jet dry” method as shown in FIG. 4A or through the use of an “ambient flash-off” method as shown in FIG. 4B. The “jet-dry” method (FIG. 4A) exposes the printed ink to a stream of heated air for less than about 5 minutes, with less than about 4 minutes being preferred. Thus, the use of this method can eliminate the need for curing the ink prior to the application of the weather resistant layer and reduce the manufacturing cycle time by about 30 to 60 minutes. The apparatus used to pre-dry the printed panel may take a variety of configurations, but each configuration directs a hot air stream over the surface of the panel. Thus, this apparatus produces, blows, or directs hot air towards the ink printed on the surface of the panel. The air may be heated to about 70° C.

A ramped heating profile may be utilized with respect to the “jet-dry” method. This ramped heating profile refers to the temperature of the air near the start or entrance of the apparatus used in step 40 being lower than the temperature of the air near the center (middle) or exit (end) of the apparatus. For example, the printed panel may enter the apparatus where it is exposed to a stream of air heated to about 50° C., while the stream of air near the exit of the apparatus is heated to about 70° C. One skilled in the art will recognize that various heating profiles or the establishment of heating zones at different temperatures may be utilized.

The “ambient flash-off” method (FIG. 4B) exposes the printed ink to air at ambient temperature for a period of about 15 to 30 minutes with about 15 minutes being preferred. Over this time the solvent in the printed ink is allowed to substantially evaporate, thereby, rendering the printed ink tack-free. Tack-free refers to a condition where the ink has set-up structure to reduce the potential of flow or run defects and is in a state that can be physically touched without the creation of physical defects. This method allows for the elimination of the curing of the ink prior to the application of the weather resistant layer, as well as a reduction in process time by about 20 to 35 minutes.

The weather resistant layer may be applied, in step 45, to the printed panel by dip coating, flow coating, spray coating, curtain coating, spin coating, or any other techniques known to one skilled-in-the-art. The thickness of the weather resistant layer may range from about 2 micrometers to several mils (1 mil=25.4 micrometers), with about 6 micrometers to 1 mil being preferred. The weather resistant layer may be applied as a single layer or as multiple sub-layers, including but not limited to, a primer and a topcoat.

The printed opaque pattern and the weather resistant layer are then cured, in step 50, preferably simultaneously. The printed opaque pattern and the weather resistant layer may be cured using a mechanism selected as one of UV absorption, thermal absorption, condensation addition, thermally driven entanglement, cross-linking induced by cationic or anionic species, or a combination thereof. The time necessary for the printed opaque pattern and the weather resistant layer to substantially cure is dependent upon the mechanism selected above. For example, when curing an opaque printed pattern and a weather resistant layer by thermal absorption, the panel may be exposed to a temperature greater than about 100° C. for greater than about 15 minutes.

The weather resistant layer is over-coated via the deposition, step 55, of an abrasion resistant layer. This abrasion resistant layer may be either comprised of one layer or a combination of multiple inter-layers of variable composition. The abrasion resistant layer may be applied by any vacuum deposition technique known to those skilled-in-the-art, including but not limited to plasma-enhanced chemical vapor deposition (PECVD), expanding thermal plasma PECVD, plasma polymerization, photochemical vapor deposition, ion beam deposition, ion plating deposition, cathodic arc deposition, sputtering, evaporation, hollow-cathode activated deposition, magnetron activated deposition, activated reactive evaporation, thermal chemical vapor deposition, and any known sol-gel coating process.

In one embodiment of the present invention, a specific type of PECVD process used to deposit the abrasion resistant layers comprising an expanding thermal plasma reactor is preferred. This specific process (called hereafter as an expanding thermal plasma PECVD process) is described in detail in U.S. Patent Publication No. 2005/0284374A1 and U.S. Patent Publication No. 2005/0202184A1, the entirety of both being hereby incorporated by reference. In an expanding thermal plasma PECVD process, a plasma is generated via applying a direct-current (DC) voltage to a cathode that arcs to a corresponding anode plate in an inert gas environment. The pressure near the cathode is typically higher than about 150 Torr, e.g., close to atmospheric pressure, while the pressure near the anode resembles the process pressure established in the plasma treatment chamber of about 20 mTorr to about 100 mTorr. The near atmospheric thermal plasma then supersonically expands into the plasma treatment chamber.

The reactive reagent for the expanding thermal plasma PECVD process may comprise, for example, octamethylcyclotetrasiloxane (D4), tetramethyldisiloxane (TMDSO), hexamethyldisiloxane (HMDSO), vinyl-D4 or another volatile organosilicon compound. The organosilicon compounds are oxidized, decomposed, and polymerized in the arc plasma deposition equipment, typically in the presence of oxygen and an inert carrier gas, such as argon, to form an abrasion resistant layer.

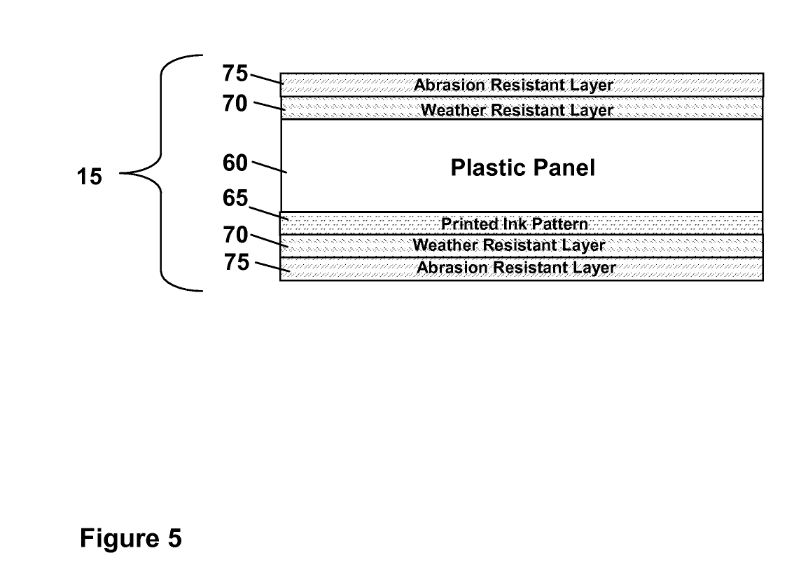

Referring now to FIG. 5, a cross-section of a plastic glazing panel according to one embodiment of the present invention is shown. The plastic panel 60 may be comprised of any thermoplastic or thermoset polymeric resin. The polymeric resins include, but are not limited to, polycarbonate, acrylic, polyarylate, polyester, and polysulfone, as well as copolymers and mixtures thereof. In order to function appropriately as a window 15, the plastic panel 60 is substantially transparent.

The ink 65 applied to the plastic panel 60 may be made of a polyester-based resin, a polycarbonate-based resin, an acrylic-based resin, or a mixture or combination thereof. The polyester-based resin may be a mixture of saturated polyesters, which are either straight or branch-chained aliphatic or aromatic polymers. These polymers may include either hydroxyl or carboxyl groups that form films via condensation polymerization with other resins (e.g., amino formaldehyde, melamine, polyisocyanates, etc.) that have complimentary reactive groups. The polycarbonate resin is based on geminally disubstituted dihydroxydiphenyl cycloalkanes. The polycarbonate-based resin may contain bifunctional carbonate structural units or hydroxyl groups. The polycarbonate backbone may be aliphatic or aromatic, as well as linear or branched. The acrylic resins may contain either hydroxyl or carboxyl functionality that can either cross-link via self-condensation of the functional groups or by reaction with the functional groups on another polymer at an elevated temperature. Hydroxyl functionality is more likely with the hydroxyl-functional resin being called a polyacrylic-polyol. Typically, the monomers utilized in the preparation of a thermoset acrylic resin include monoallyl ethers of polyols, hydroxyethyl methacrylate, hydroxypropyl methacrylate, or hydroxypropyl acrylate. The most chemical resistant and hydrolytically stable resins result from either high alkyl methacrylates (e.g., methyl methacrylate, butyl methacrylate, etc.), acrylates with ethyl side chains (e.g., 2-ethyl hexylacrylate, etc.), or itaconic acid.

The ink 65 may include various additives, such as pigments, dispersants, catalysts or cross-linking agents, as well as various types of solvents. For example, a polyester ink may comprise a dispersion of a polyester resin mixture, titanium oxide, carbon black, gamma-butyrolactone, aliphatic dibasic acid ester and other colorant pigments in a mixture of various solvents, such as petroleum distillate, cyclohexanone mixture, and naphthalene solvents. An example of an ink suitable for use in the present invention is Exatec® PIX offered by Exatec LLC, Wixom, Mich. or its licensed suppliers.

The pigments in the ink 65 may include, but not be limited to, carbon black, copper phtahocyanine blue, dioxazine violet, quinacridone magenta, azo diarylide yellow, rutile titanium dioxide (white), perylene red, molybdate orange, yellow iron oxide, chromium green oxide, or cadmium orange. Special effect pigments, such as pearlescent pigments and metallic flakes, may be incorporated into the formulation.

An example of a cross-linking additive found to be useful to enhance the solvent resistance of the inks 65 is an aromatic polyisocyanate, such as the NB-70 catalyst (Nazdar Inc., Kansas). This particular isocyanate is dispersed in propylene glycol methyl ether acetate (40%, also called PM acetate) although other solvents could be utilized. The isocyanate can also be other aromatic or aliphatic diisocyanates, such as polymeric hexamethylene diisocyanate (HMDI), isophorone diisocyanate (IPDI), 2,6-tolylene diisocyanate (TDI), diphenylmethane diisocyanate (MDI), or xylene diisocyanate (XDI), among others.

A dispersant used in the ink 65 may be any ionic or nonionic dispersing agent. Such surfactants include but are not limited to metallic soaps, sulfonates, phosphate esters, fatty acid esters, fluoroaliphatic polymeric esters, titanate or ziconate or aluminate coupling agents, organomodified polysiloxanes, block copolymers of poly(alkylene oxide), and commercial proprietary surfactants, such as Hypermer® and Solsperse® hyperdispersants (ICI Americas, Inc.). An example of an organomodified polysiloxane dispersant is a polyether siloxane copolymer, such as Tego® Wet KL 245 (Goldshmidt Chemical Corp., Virginia).

Any opacity enhancing fillers used in the inks 65 may be inorganic in nature, such as alumina, silica, titanium dioxide, magnesium silicate (talc), barium sulfate, calcium carbonate, aluminum silicate (clay), calcium silicate (wollastonite), aluminum potassium silicate (mica), metallic flakes, etc., or organic in nature, such as furnace black, channel black, and lamp black, among others. Highly refractive fillers, such as titanium dioxide, are preferred for increasing opacity due to their small mean particle size of less than 1.0 micrometer. For example, titanium dioxide having a mean particle size of 0.36 micrometers is available as Ti-Pure® R-706 (DuPont Titanium Technologies, Delaware).

The weather resistant layer 70 may be comprised of, but not limited to, silicones, polyurethanes, acrylics, polyesters, polyurethane acrylates, and epoxies, as well as mixtures or copolymers thereof. The weather resistant layer 70 preferably includes ultraviolet (UV) absorbing molecules, such as hydroxyphenyltriazine, hydroxybenzophenones, hydroxylphenylbenzotriazoles, hydroxyphenyltriazines, polyaroylresorcinols, 2-(3-triethoxysilylpropyl)-4,6-dibenzoylresorcinol) (SDBR), 4,6-dibenzoylresorcinol (DBR), and cyanoacrylates, among others to protect the underlying plastic panel 60 and printed ink 65 from degradation caused by exposure to the outdoor environment.

The weather resistant layer 70 may be comprised of one homogenous layer (e.g., primerless) or multiple sub-layers (e.g., primer and topcoat). A primer typically aids in adhering the topcoat to the plastic panel. The primer for example may include, but not be limited to, acrylics, polyesters, epoxies, and copolymers and mixtures thereof. Similarly, the topcoat may include, but not be limited to, polymethylmethacrylate, polyvinylidene fluoride, polyvinylfluoride, polypropylene, polyethylene, polyurethane, silicone, polymethacrylate, polyacrylate, polyvinylidene fluoride, silicone hardcoat, and mixtures or copolymers thereof. One specific example of a weather resistant layer 70 comprising multiple sub-layers is the combination of an acrylic primer (SHP-9X, Exatec LLC, Wixom, Mich.) with a silicone hard-coat (AS4000 or AS4700, Momentive Performance Materials; or SHX, Exatec LLC).

A variety of additives may be added to the weather resistant layer 70, e.g., to either or both the primer and the topcoat, such as colorants (tints), rheological control agents, mold release agents, antioxidants, and IR absorbing or reflecting pigments, among others. The type of additive and the amount of each additive is determined by the performance required by the plastic glazing panel to meet the specification and requirements for use as a window 15.

The abrasion resistant layer 75 may be comprised of aluminum oxide, barium fluoride, boron nitride, hafnium oxide, lanthanum fluoride, magnesium fluoride, magnesium oxide, scandium oxide, silicon monoxide, silicon dioxide, silicon nitride, silicon oxy-nitride, silicon oxy-carbide, hydrogenated silicon oxy-carbide, silicon carbide, tantalum oxide, titanium oxide, tin oxide, indium tin oxide, yttrium oxide, zinc oxide, zinc selenide, zinc sulfide, zirconium oxide, zirconium titanate, or a mixture or blend thereof. Preferably, the abrasion resistant layer 75 is comprised of a composition ranging from SiOₓ to SiOₓC_{y}H_{z} depending upon the amount of carbon and hydrogen atoms that remain in the deposited layer.

The plastic glazing panel must pass multiple tests that have been specified by automotive original equipment manufacturers (OEM) prior to being used as an automotive window 15. Such tests include a water immersion test at elevated temperatures, and a Cataplasma test. Unless the ink 65 and protective coatings (weather resistant 70 and abrasion resistant 75 layers) pass all the tests specified, the plastic glazing panel can not be used as a window 15 in the assembled motor vehicle. For plastic glazing, it also is desirable that the printed ink 65 provide opacity greater than about 95% with greater than 99.8% being preferred due to current “glass” glazing regulatory constraints. One skilled-in-the-art will recognize that the current opacity requirement may be relaxed for plastic glazing due to the use of coatings that absorb UV radiation, thereby, providing the necessary level of protection for any underlying adhesive bond similar to the level that is provided in a glass glazing panel by insuring near complete opacity of the ink.

The water immersion test includes an initial cross-hatch adhesion test (tape pull) according to ASTM D3359-95 followed by submersing the printed plastic glazing panels in distilled water at elevated temperatures around 65° C. for approximately 10 days. The adhesion of the ink 65 and protective layers (i.e., weather resistant 70 & abrasion resistant 75 layers) is tested about every other day up to the maximum of 10 days. A plastic glazing panel passes the test only if greater than 95% retention of the ink 65 and protective layers (70 & 75) is obtained on the 10^{th} day.

The Cataplasma test involves applying the following adhesive primers and adhesive: (1) Betaseal™ 43518—clear primer; (2) Betaseal™ 48520A—black primer; and (3) Betaseal™ 57302—urethane adhesive (Dow Automotive, Auburn Hills, Mich.) to the plastic glazing panel. The portion of the plastic glazing panel being tested should be large enough to apply two adhesive beads (i.e., each bead about 1 inch wide and no less than about 9 inches in length). The test protocol is well known to one skilled-in-the-art as Dow Automotive AG, Test Method No. 039E—Cataplasma Treatment.

The Cataplasma test exposes the plastic glazing panel along with cured adhesive beads applied to the surface of the glazing panel to high humidity at an elevated temperature followed by a low temperature shock (i.e., wrapping the panel for 7 days in wet cotton at 70° C. followed by 3 hrs at −20° C.). Prior to exposing the glazing panel to high humidity, one adhesive bead is pulled and the degree of cohesive failure evaluated in this “Pre-test” pull. In order to pass this initial adhesive pull, greater than 95% cohesive failure of the adhesive needs to be observed. The glazing panel is then exposed to the high humidity cycling as stated above. Upon completion of the testing, and after being equilibrated at room temperature (about 23° C.), the plastic glazing panel is subjected to visual inspection for optical changes or defects, such as the development of haze, color change, blisters, and microcracks. Finally, another adhesive bead is pulled on each sample and the degree of cohesive failure of the adhesive is examined once again in this “post-test” pull. In order for a printed plastic glazing panel to pass the Cataplasma test there must be no change in optical appearance and greater than 75% cohesive failure of the adhesive in the post-test pull. Therefore, for a plastic glazing panel to pass the above test, the entire glazing panel, i.e., plastic panel 60/cured ink 65/cured weather resistant layer 70/abrasion resistant layer 75 must exhibit a high level of hydrolytic stability at different temperatures and moisture conditions.

The following specific examples are given to illustrate the invention and should not be construed to limit the scope of the invention.

### EXAMPLE 1

### “Jet Dry” Method

Fourteen polycarbonate panels 60 were formed and subsequently screen printed with Exatec® PIX ink (Exatec LLC, Wixom, Mich.). The printed panels were then pre-dried using the “jet dry” method by subjecting the printed ink 65 to a flow of air heated to 70° C. for either 2 minutes (Run #'s 1-4 & 9-11) or 4 minutes (Run #'s 5-8 & 12-14). The decorated panels were subsequently coated with a weather resistant layer (Exatec® SHP-9X acrylic primer and Exatec® SHX silicon hard-coat, Exatec LLC, Wixom, Mich.) and cured according to the manufacturer's specifications. An abrasion resistant layer 75 was then deposited on top of the weather resistant layer 70 using an expanding thermal plasma PECVD method. The resulting protective coating system (weather resistant 70 and abrasion resistant 75 layers) is known as the Exatec® 900 glazing system (Exatec LLC, Wixom, Mich.) used in conjunction with polycarbonate windows 15.

The decorated glazing panels were then subjected to either water immersion at 65° C. (Run #'s 1-8) or Cataplasma testing (Run #'s 9-14) according to the previously described procedures. In the water immersion test, cross-hatch adhesion according to ASTM D3359-95 was measured at the start of the test (Day 0) and after completion of the test (10 days). In order to pass this adhesion test, greater than 95% retention of the coating layers (70 & 75) and ink 65 on the polycarbonate panel 60 is required. All of decorated panels (Run #'s 1-8) were found to exhibit about 99-100% adhesion retention as shown in Table 1. Thus, all of the decorated panels passed the water immersion test.

In the Cataplasma test, the percent (%) cohesive failure of an adhesive bead applied to the surface of the decorated glazing panel was measured at the start of the test (Pre-Pull) and after completion of the test (Post-Pull). In order to pass this test, greater than 95% cohesive failure of the adhesive must be observed in the pre-pull test and greater than 75% cohesive failure of the adhesive must occur in the post-pull test. All of the decorated panels (Run #'s 9-14) were found to exhibit between about 99-100% cohesive failure of the adhesive bead in both the pre-pull and post-pull tests as shown in Table 1. Thus all of the decorated panels passed the Cataplasma test.

This example demonstrates that the weather resistant layer 70 can be applied on a tack free, but not substantially cured, ink layer and that the ink 65 and the weather resistant layer 70 can be cured during the same curing step 50 according to one embodiment of the present invention. In this embodiment the tack free, pre-dried condition was established using a “jet dry” method.

TABLE 1
Water Immersion Test

% retention

| | Pre-Dry Time | Day 0 | Day 10 |
|---|---|---|---|
| Run 1 | 2 minutes | 100 | 100 |
| Run 2 | 2 minutes | 100 | 100 |
| Run 3 | 2 minutes | 100 | 100 |
| Run 4 | 2 minutes | 100 | 100 |
| Run 5 | 4 minutes | 100 | 100 |
| Run 6 | 4 minutes | 100 | 100 |
| Run 7 | 4 minutes | 100 | 99 |
| Run 8 | 4 minutes | 100 | 100 |

Cataplasma Test

% Cohesive
Failure

| | Pre-Dry Time | Pre-Pull | Post-Pull |
|---|---|---|---|
| Run 9 | 2 minutes | 100 | 100 |
| Run 10 | 2 minutes | 100 | 100 |
| Run 11 | 2 minutes | 100 | 99 |
| Run 12 | 4 minutes | 100 | 100 |
| Run 13 | 4 minutes | 100 | 100 |
| Run 14 | 4 minutes | 100 | 99 |

### EXAMPLE 2

### Ambient Flash-Off Method

Sixteen polycarbonate panels 60 were formed and subsequently screen printed with Exatec® PIX ink (Exatec LLC, Wixom, Mich.). The printed panels were then pre-dried using the “ambient flash-off” method by subjecting the printed ink 65 to ambient air (at about 22° C.) for either 15 minutes (Run #'s 15-20 & 27-28) or 60 minutes (Run #'s 21-26 & 29-30). The decorated panels were subsequently coated with a weather resistant layer 70 (Exatec® SHP-9X acrylic primer and Exatec® SHX silicon hard-coat, Exatec LLC, Wixom, Mich.) and cured according to the manufacturer's specifications. An abrasion resistant layer 75 was then deposited on top of the weather resistant layer 70 using an expanding thermal plasma PECVD method. The resulting protective coating system (weather resistant 70 and abrasion resistant 75 layers) is known as the Exatec® 900 glazing system (Exatec LLC, Wixom, Mich.) used in conjunction with polycarbonate windows 15.

The decorated glazing panels were then subjected to either water immersion at 65° C. (Run #'s 15-26) or Cataplasma testing (Run #'s 27-30) according to the previously described procedures. In the water immersion test, cross-hatch adhesion according to ASTM D3359-95 was measured at the start of the test (Day 0) and after completion of the test (10 days). In order to pass this adhesion test, greater than 95% retention of the coating layers (70 & 75) and ink 65 on the polycarbonate panel 60 is required. All of decorated panels (Run #'s 15-26) were found to exhibit about 99-100% adhesion retention as shown in Table 2. Thus all of the decorated panels passed the water immersion test.

In the Cataplasma test, the percent (%) cohesive failure of an adhesive bead applied to the surface of the decorated glazing panel was measured at the start of the test (Pre-Pull) and after completion of the test (Post-Pull). In order to pass this test, greater than 95% cohesive failure of the adhesive must be observed in the pre-pull test and greater than 75% cohesive failure of the adhesive must occur in the post-pull test. All of the decorated panels (Run #'s 27-30) were found to exhibit between about 99-100% cohesive failure of the adhesive bead in both the pre-pull and post-pull tests as shown in Table 2. Thus all of the decorated panels passed the Cataplasma test.

TABLE 2
Water Immersion Test

% retention

| | Pre-Dry Time | Day 0 | Day 10 |
|---|---|---|---|
| Run 15 | 15 minutes | 100 | 99 |
| Run 16 | 15 minutes | 100 | 99 |
| Run 17 | 15 minutes | 100 | 99 |
| Run 18 | 15 minutes | 100 | 99 |
| Run 19 | 15 minutes | 100 | 99 |
| Run 20 | 15 minutes | 100 | 99 |
| Run 21 | 60 minutes | 100 | 99 |
| Run 22 | 60 minutes | 100 | 99 |
| Run 23 | 60 minutes | 100 | 99 |
| Run 24 | 60 minutes | 100 | 99 |
| Run 25 | 60 minutes | 100 | 99 |
| Run 26 | 60 minutes | 100 | 99 |

Cataplasma Test

% Cohesive
Failure

| | Pre-Dry Time | Pre-Pull | Post-Pull |
|---|---|---|---|
| Run 27 | 12 minutes | 99 | 100 |
| Run 28 | 15 minutes | 100 | 96 |
| Run 29 | 60 minutes | 100 | 100 |
| Run 30 | 60 minutes | 100 | 100 |

This example demonstrates that the weather resistant layer 70 can be applied on a tack free, but not substantially cured, ink layer and that the ink 65 and the weather resistant layer 70 can be cured during the same curing step 50 according to one embodiment of the present invention. In this embodiment the tack free, pre-dried condition was established using an “ambient flash-off” method.

A person skilled in the art will recognize from the previous description that modifications and changes can be made to the present disclosure without departing from the scope of the disclosure as defined in the following claims. A person skilled in the art will further recognize that the measurement of cross-hatch adhesion and the degree of cohesive failure of an adhesive in a Cataplasma test are standard measurements that can be obtained by a variety of different test methods and protocols. The test methods described in the examples represents only one available method to obtain each of the required measurements.

What is claimed is:

1. A method of manufacturing a plastic glazing panel, the method comprising the steps of:
forming a substantially transparent plastic panel;
printing an opaque pattern from an ink, the opaque pattern being in contact with the plastic panel;
pre-drying the ink of the opaque pattern to a tack-free condition;
applying a weather resistant layer on the opaque pattern and on the plastic panel;
curing the ink of the opaque pattern;
curing the weather resistant layer; and
depositing an abrasion resistant layer on the weather resistant layer;
wherein the pre-drying of the ink substantially removes the solvent therein without substantially curing the ink.

2. A method of manufacturing a plastic glazing panel of claim 1, wherein the pre-drying step forces heated air onto or over the surface of the printed ink.

3. A method of manufacturing a plastic glazing panel of claim 2, wherein the air is heated to about 70° C.

4. A method of manufacturing a plastic glazing panel of claim 2, wherein the heating of the air is ramped from about 50° C. near the beginning of the pre-drying step to about 70° near the end of the pre-drying step.

5. A method of manufacturing a plastic glazing panel of claim 2, wherein the pre-drying step is performed in less than about 5 minutes.

6. A method of manufacturing a plastic glazing panel of claim 5, wherein the pre-drying step is performed for about 2 to 4 minutes.

7. A method of manufacturing a plastic glazing panel of claim 1, wherein the pre-drying step includes a flash-off period at ambient temperature of less than about 30 minutes.

8. A method of manufacturing a plastic glazing panel of claim 7, wherein the flash-off period of the pre-drying step is completed in less than about 15 minutes.

9. A method of manufacturing a plastic glazing panel of claim 1, wherein the curing of the printed ink occurs simultaneously with the curing of the weather resistant layer.

10. A method of manufacturing a plastic glazing panel of claim 9, wherein the step of curing the printed ink and the weather resistant layer includes a method selected as one of UV absorption, thermal absorption, condensation addition, thermally driven entanglement, cross-linking induced by cationic or anionic species, or a combination thereof.

11. A method of manufacturing a plastic glazing panel of claim 1, wherein the printing step prints a decorative border on the plastic panel.

12. A method of manufacturing the plastic glazing panel of claim 1, wherein the step of forming the plastic panel includes a method selected from injection molding, blow molding, compression molding, thermal forming, vacuum forming, and cold forming.

13. A method of manufacturing the plastic glazing panel of claim 1, wherein the ink printing step includes a method selected from screen printing, pad printing, or ink jet printing.

14. A method of manufacturing the plastic glazing panel of claim 1, wherein the step of applying the weather resistant layer uses a method selected as one of flow coating, spray coating, curtain coating, dip coating, or spin coating.

15. A method of manufacturing the plastic glazing panel of claim 1, wherein the step of depositing an abrasion resistant layer uses a vacuum deposition technique.

16. A method of manufacturing the plastic glazing panel of claim 15, wherein the step of depositing an abrasion resistant layer uses a vacuum deposition technique selected from plasma-enhanced chemical vapor deposition (PECVD), expanding thermal plasma PECVD, plasma polymerization, photochemical vapor deposition, ion beam deposition, ion plating deposition, cathodic arc deposition, sputtering, evaporation, hollow-cathode activated deposition, magnetron activated deposition, activated reactive evaporation, thermal chemical vapor deposition, and any known sol-gel coating process.

17. A method of manufacturing the plastic glazing panel of claim 1, wherein the step of forming the plastic panel occurs after the step of printing and pre-drying the printed pattern and before the step of applying the weather resistant coating.

18. A plastic glazing panel made by the method of claim 1.

19. The plastic glazing panel of claim 18, wherein greater than about 95% of the printed ink pattern, weather resistant layer, and abrasion resistant layer are retained after being tested according to ASTM D3359-95 for greater than 9 days of water immersion at about 65° C.

20. The plastic glazing panel of claim 18, wherein greater than about 75% cohesive failure of an adhesive bead applied to the surface of the glazing panel occurs upon exposure to high temperature and humidity in a Cataplasma Treatment Test (Method No. 039E, Dow Automotive).
